(19) United States
(12) Patent Application Publication
(10) Pub. No.: US 2026/0239713 A1
(43) Pub. Date: Aug. 13, 2026

(54) STATIC RANDOM ACCESS MEMORY (SRAM) WITH HYBRID GATE STRUCTURES

(71) Applicant: Taiwan Semiconductor Manufacturing Company, Ltd., Hsinchu (TW)

(72) Inventors: Ping-Wei Wang, Hsinchu City (TW); Jui-Lin Chen, Hsinchu City (TW)

(73) Assignee: Taiwan Semiconductor Manufacturing Company, Ltd., Hsinchu (TW)

(21) Appl. No.: 19/049,639

(22) Filed: Feb. 10, 2025

(51) Int. Cl. H10D 64/27; H10B 10/00; H10D 64/66

(52) U.S. Cl. CPC H10D 64/519; H10B 10/12; H10D 64/518; H10D 64/667

(57) ABSTRACT

A memory device may comprise a memory cell including first, second, third, fourth, fifth, sixth, and seventh transistors. The first to third transistors can be operatively formed from a first active region extending along a first lateral direction and each may have a respective gate structure extending along a second lateral direction. The fourth to seventh transistors can be operatively formed from a second active region extending along the first lateral direction and each may have a respective gate structure extending along the second lateral direction. The gate structures of the first to third transistors each may have a first measurement extending in the first lateral direction. The gate structures of the fourth to seventh transistors each may have a second measurement extending in the first lateral direction. The first measurement can be shorter than the second measurement.

### BACKGROUND

The semiconductor industry has experienced rapid growth due to continuous improvements in the integration density of a variety of electronic components (e.g., transistors, diodes, resistors, capacitors, etc.). Static Random Access Memory (SRAM) is a type of volatile memory that retains data as long as power is supplied, making it faster and more reliable than Dynamic Random Access Memory (DRAM). SRAM cells utilize bistable latching circuitry, which allows them to maintain their state without the need for periodic refreshing, distinguishing them from other memory types.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example layout design of an example memory device with hybrid gate structures, in accordance with some embodiments.

FIG. 2 illustrates an example layout design of an example memory device with hybrid gate structures, in accordance with some embodiments.

FIG. 3 is a cross-sectional view of an example memory device with hybrid gate structures, in accordance with some embodiments.

FIG. 4 illustrates an example layout design of an example memory device with hybrid gate structures, in accordance with some embodiments.

FIG. 5 illustrates an example layout design and a cross-sectional view of an example memory device, in accordance with some embodiments.

FIG. 6 illustrates an example layout design and a cross-sectional view of an example memory device, in accordance with some embodiments.

FIG. 7 illustrates an example layout design of an example memory device with hybrid gate structures, in accordance with some embodiments.

FIG. 8 illustrates an example layout design of an example memory device with hybrid gate structures, in accordance with some embodiments.

FIG. 9 illustrates an example table of different implementation examples of memory devices with hybrid gate structures, in accordance with some embodiments.

FIG. 10 illustrates an example layout design of an example memory device with hybrid gate structures, in accordance with some embodiments.

FIG. 11 illustrates an example flow chart for forming a memory device, in accordance with some embodiments.

FIG. 12 illustrates an example layout design of an example memory device with hybrid gate structures, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A static random access memory (SRAM) device is a type of volatile semiconductor memory that stores data bits using bi-stable circuitry. Bi-stable circuitry will maintain the integrity of a stored bit without refreshing. A NPMOS PG SRAM technology is designed to achieve high-speed performance while optimizing SRAM Vmin in NPMOS PG configurations. In some embodiments, a read speed in NPMOS PG SRAM plays a dominant role in the overall performance of a read pass gate (RPG), which can be important for fast data access. However, the introduction of turn-on write assist can lead to a deterioration in Vmin at lower supply voltages (Vddr), primarily due to the weak PMOS transistors that are employed. This interplay between speed optimization and stability presents significant challenges in maintaining reliable performance across various operating conditions in NPMOS PG SRAM devices. In some embodiments, a weak pull-up transistor can lead to higher Vddr levels, increasing the risk of read disturbance during memory operations.

A NPMOS PG SRAM device with hybrid metal gate (MG) technology is designed to optimize Vmin while enhancing overall device performance. By reducing the measurements/dimensions of the gate structures in an SRAM device, the read speed can be significantly improved, allowing for faster access times and increased efficiency in data retrieval. Additionally, this reduction in gate dimensions can contribute to a decrease in supply voltages (Vddr), which is critical for minimizing power consumption in SRAM devices. The present application can be applied to both 7-transistor (7T) and 8-transistor (8T) configurations, highlighting its versatility and effectiveness in advancing NPMOS PG SRAM technology. These are, of course, merely examples and are not intended to be limiting.

The implementation of reduction in gate dimensions/measurements/lengths (e.g., Lg−a) enhances the speed of NPMOS PG SRAM devices. Specifically, shortening the dimensions/measurements/lengths in NPMOS PG SRAM devices can enhance speed, which leads to faster switching times and improved performance. A shorter gate allows for quicker transistor activation, boosting the overall speed of the device. For example, using the gate dimensions (e.g., Lg−a) in the pull-up (PU) and read pass gate (RPG) transistors results in a speed improvement of about 4%. In some embodiments, the reduction in gate dimensions contributes to a notable reduction in supply voltages (Vddr), achieving improvements in the range of about 50 to 700 mV when the ratio of PU gate length/dimension (e.g., PU Lg) to pull-down (PD) gate length/dimension (e.g., PD Lg) is less than 1 (e.g., pull-up (PU) gate length/pull-down (PD) gate length<1), while maintaining a ratio of pull-down (PD) gate length Lg to NMOS pass gate (NPG) length Lg at 1. These advancements demonstrate the effectiveness of hybrid gate structures in optimizing both speed and power efficiency in SRAM configurations.

The present disclosure provides various embodiments of a memory device comprising a memory cell. The memory cell may include first (e.g., pull-up (PU) transistor), second (e.g., PU transistor), third (e.g., read pass gate (RPG) transistor), fourth (e.g., pass gate (PG) transistor), fifth (e.g., pull-down (PD) transistor), sixth (e.g., PD transistor), and seventh transistors (e.g., PG transistor). The first, second, and third transistors may have a first conductive type (e.g., P-type). The fourth, fifth, sixth, and seventh transistors may have a second conductive type (e.g., N-Type). The first to third transistors can be operatively formed from a first active region (e.g., OD active region) extending along a first lateral direction (e.g., X-direction) and each may have a respective gate structure extending along a second lateral direction (e.g., Y-direction). The fourth to seventh transistors can be operatively formed from a second active region (e.g., OD active region) extending along the first lateral direction (e.g., X-direction) and each may have a respective gate structure extending along the second lateral direction (e.g., Y-direction). The gate structures of the first to third transistors each may have a first length/measurement/dimension (e.g., Lg−a) extending in the first lateral direction (e.g., X-direction). The gate structures of the fourth to seventh transistors each may have a second length/measurement/dimension (e.g., Lg) extending in the first lateral direction. The first measurement (e.g., Lg−a) can be shorter than the second measurement (e.g., Lg). The proposed memory device structures enhance speed and improve supply voltage in SRAM configurations.

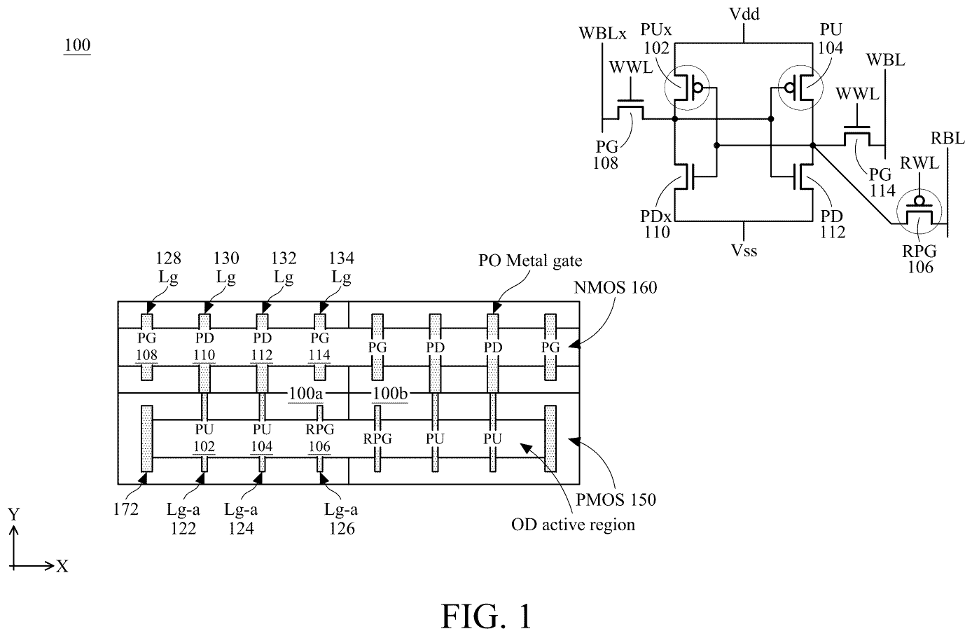

FIG. 1 illustrates an example layout design of an example memory device (e.g., SRAM) 100 with hybrid gate structures, in accordance with some embodiments. FIG. 1 shows a memory device 100 with a plurality of memory cells 100a, 100b. One or more peripheral circuits (not shown) may be located at one or more regions peripheral to, or within, the memory cells 100a, 100b. In the illustrated embodiment of FIG. 1, the memory cell can be an example of a seven transistor (7T) SRAM cell 100a, 100b. The memory cell 100a, 100b may include first (e.g., pull-up (PU) transistor) transistor 102, second (e.g., PU transistor) transistor 104, third (e.g., read pass gate (RPG) transistor) transistor 106, fourth (e.g., pass gate (PG) transistor) transistor 108, fifth (e.g., pull-down (PD) transistor) transistor 110, sixth (e.g., PD transistor) transistor 112, and seventh (e.g., PG transistor) transistor 114. In some embodiments, the memory cell may include a Static Random Access Memory (SRAM) cell.

In some embodiments, the memory cell 100a, 100b may include a cross-coupled inverter including PMOS transistors PUx 102, PU 104 and NMOS transistors PDx 110, PD 112. NMOS transistor PG 108 can be coupled to a bit line (WBLx) and to the cross-coupled inverter. The gate of NMOS transistor PG 108 can be coupled to a write word line (WWL). NMOS transistor PG 114 can be coupled to the cross-coupled inverter and to a bit line bar (WBL). The gate of NMOS transistor PG 114 is coupled to WWL. Read port transistor RPG 106, which functions as a read pass gate (RPG) transistor, has its gate coupled to a read word line (RWL), its source coupled to the cross-coupled inverter, and its drain coupled to a read bit line (RBL).

In some embodiments, the first transistor 102, second transistor 104, and third transistor 106 may have a first conductive type (e.g., PMOS). The first to third transistors can be operatively formed from a first active region (e.g., oxide diffusion (OD) active region) 150 extending along a first lateral direction (e.g., X-direction). Each of the first to third transistors may have a respective gate structure 122, 124, 126 extending along a second lateral direction (e.g., Y-direction). The gate structures of the first to third transistors each may have a first length/measurement/dimension (e.g., Lg−a) extending in the first lateral direction.

In some embodiments, the fourth transistor 108, fifth transistor 110, sixth transistor 112, and seventh transistor 114 may have a second conductive type (e.g., NMOS). The fourth to seventh transistors can be operatively formed from a second active region (e.g., OD active region) 160 extending along the first lateral direction (e.g., X-direction). Each of the fourth to seventh transistors may have a respective gate structure 128, 130, 132, 134 extending along the second lateral direction (e.g., Y-direction). The gate structures of the fourth to seventh transistors each may have a second length/measurement/dimension (e.g., Lg) extending in the first lateral direction. In some embodiments, the first length/measurement/dimension (e.g., Lg−a) can be shorter than the second length/measurement/dimension (e.g., Lg). In some embodiments, the first measurement and the second measurement can be different from each other with a difference (e.g., a). A ratio of the difference to the second measurement (e.g., a/Lg) can be between about 0.05 and about 0.5 (e.g., 0.05<a/Lg<0.5).

In some embodiments, the gate structure 122 of the first transistor 102 and the gate structure 130 of the fifth transistor 110 can be connected to each other along the second lateral direction (e.g., Y-direction). In some embodiments, the gate structure 124 of the second transistor 104 and the gate structure 132 of the sixth transistor 112 can be connected to each other along the second lateral direction (e.g., Y-direction). In some embodiments, the gate structure 134 of the seventh transistor 114 and the gate structure 126 of the third transistor 106 can be disconnected from but aligned with each other along the second lateral direction (e.g., Y-direction).

In some embodiments, the gate structure 128 of the fourth transistor 108 can be disconnected from but aligned with another gate structure 172 traversing the first active region 150. In some embodiments, the gate structure 128 of the fourth transistor 108 and the another gate structure 172 may include one or more similar metal materials. In some embodiments, the first active region 150 may terminate at the another gate structure 172 along the first lateral direction (e.g., X-direction).

In a static random-access memory (SRAM), NMOS and PMOS transistors can be formed in oxide definition (OD) areas 150, 160. The OD area, sometimes labeled as an “oxide diffusion” area, defines an active area for each transistor, i.e., the area where the source, drain and channel under the gate of transistor are formed. The OD can be defined to be between inactive areas, such as shallow trench isolation (STI) or field oxide (FOX) areas. An OD area may include PMOS or NMOS transistors. In certain embodiments, a discontinuity (gap) separates adjacent OD regions.

In some embodiments, the memory/semiconductor device 100 may comprise a first active region 160, a second active region 150, a first gate structure 128, a second gate structure 130, 122, a third gate structure 132, 124, a fourth gate structure 134, and a fifth gate structure 126. The first active region 160 may extend along a first lateral direction (e.g., X-direction) and may have a first conductive type (e.g., N-type). The second active region 150 may extend along the first lateral direction (e.g., X-direction) and may have a second conductive type (e.g., P-type).

In some embodiments, the first gate structure 128 may extend along a second lateral direction (e.g., Y-direction) perpendicular to the first lateral direction (e.g., X-direction) and may traverse only the first active region 160. The second gate structure 130, 122 may extend along the second lateral direction (e.g., Y-direction) and may traverse both the first 160 and second 150 active regions. The third gate structure 132, 124 may extend along the second lateral direction (e.g., Y-direction) and may traverse both the first 160 and second 150 active regions. The fourth gate structure 134 may extend along the second lateral direction (e.g., Y-direction) and may traverse only the first active region 160. The fifth gate structure 126 may extend along the second lateral direction (e.g., Y-direction) and may traverse only the second active region 150. In some embodiments, the first gate structure 128, a first portion 130 of the second gate structure traversing the first active region, a first portion 132 of the third gate structure traversing the first active region, and the fourth gate structure 134 each have a first length/measurement/dimension (e.g., Lg) in the first lateral direction (e.g., X-direction). The second portion 122 of the second gate structure traversing the second active region, a second portion 124 of the third gate structure traversing the second active region, and the fifth gate structure 126 each may have a second length/measurement/dimension (e.g., Lg−a) in the first lateral direction (e.g., X-direction). In some embodiments, the first length/measurement/dimension (e.g., Lg) can be longer than the second length/measurement/dimension (e.g., Lg−a). In some embodiments, the first measurement and the second measurement can be different from each other with a difference (e.g., a). A ratio of the difference to the first length/measurement/dimension (e.g., a/Lg) can be between about 0.05 and about 0.5 (e.g., 0.05<a/Lg<0.5).

The present application provides a 7T SRAM cell that employs a hybrid metal gate configuration designed to enhance read speed by leveraging improvements in PMOS performance. The pull-up (PU) and the read pass gate (RPG) transistors utilize a reduced gate dimension (e.g., Lg−a), where Lg was a metal gate that serves both PG and pull-down (PD) functions. For example, the parameters can be within specific ranges, with about 0.5 nm<a<about 5 nm or with about 0.05<a/Lg<about 0.5, allowing for optimized device characteristics. The pull-up threshold voltage (Vt) can be set at −15 mV, contributing to a performance enhancement of about 3 to 4%. Consequently, the overall read speed can be also improved by about 3 to 4%. The NMOS transistors may retain their gate length/dimension (e.g., Lg) to meet sigma requirements, ensuring that there is no degradation in performance while achieving these enhancements.

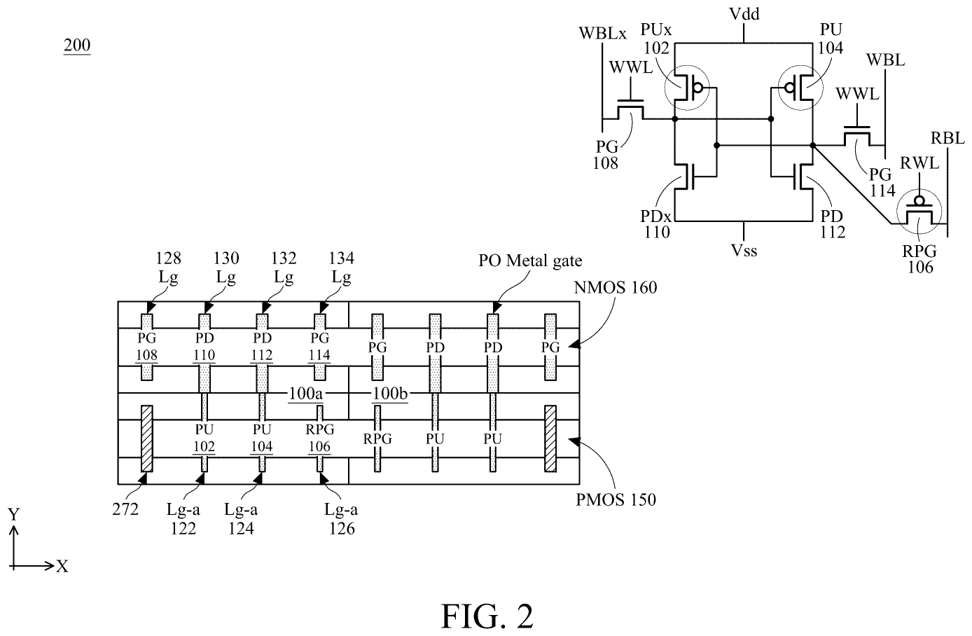

FIG. 2 illustrates an example layout design of an example memory device with hybrid gate structures, in accordance with some embodiments. FIG. 2 illustrates an alternative example of FIG. 1 by introducing another gate structure 272. FIG. 2 shows a memory device 100 with a plurality of memory cells 100a, 100b. One or more peripheral circuits (not shown) may be located at one or more regions peripheral to, or within, the memory cells 100a, 100b. In the illustrated embodiment of FIG. 2, the memory cell can be an example of a seven transistor (7T) SRAM cell 100a, 100b. The memory cell 100a, 100b may include first (e.g., pull-up (PU) transistor) transistor 102, second (e.g., PU transistor) transistor 104, third (e.g., read pass gate (RPG) transistor) transistor 106, fourth (e.g., pass gate (PG) transistor) transistor 108, fifth (e.g., pull-down (PD) transistor) transistor 110, sixth (e.g., PD transistor) transistor 112, and seventh (e.g., PG transistor) transistor 114. In some embodiments, the memory cell may include a Static Random Access Memory (SRAM) cell. The memory device 200 of FIG. 2 is substantially similar to the memory device 100 of FIG. 1, except for another gate structure 272.

In some embodiments, the gate structure 128 of the fourth transistor 108 can be disconnected from but aligned with another gate structure 272 traversing the first active region 150. In some embodiments, the gate structure 128 of the fourth transistor 108 and the another gate structure 272 can be formed of respective different materials. The first active region 150 may extend beyond the another gate structure 272 along the first lateral direction (e.g., X-direction).

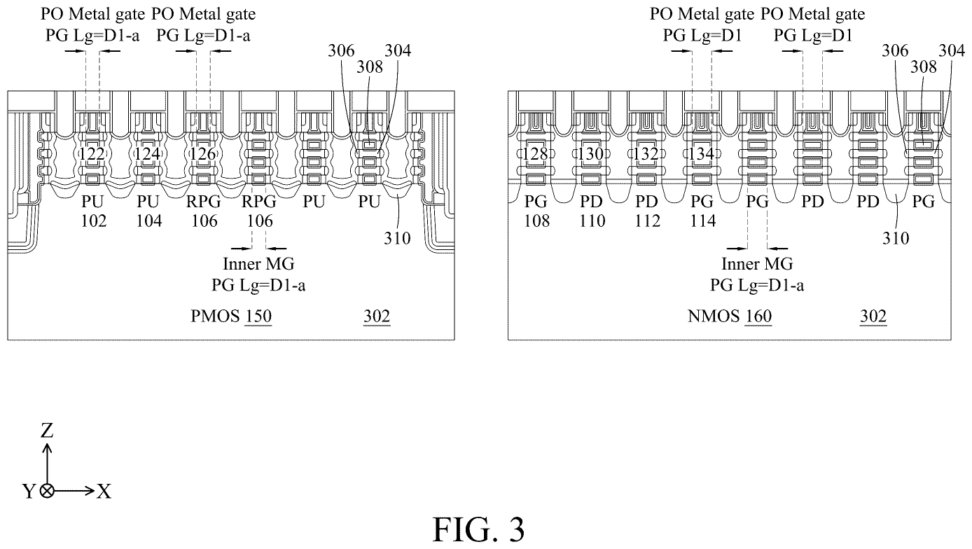

FIG. 3 is a cross-sectional view of an example gate-all-around (GAA) field-effect-transistor (FET) device/memory device 100 with hybrid gate structures, in accordance with some embodiments. The cross-sectional view of FIG. 3 is cut along the lengthwise direction of the memory device 100 (e.g., X direction).

FIG. 3 depicts a simplified GAA FET device/memory device 100, and thus, it should be understood that one or more features of a completed GAA FET device/memory device may not be shown in FIG. 3. The memory device 100 includes a substrate 302 and a number of nanostructures (e.g., nanosheets, nanowires, etc.) 304 above the substrate 302. The nanostructure 304 are vertically separated from one another. In some embodiments, the nanostructure 304 can serve as sacrificial layers and channel layers, respectively. Isolation regions 310 are formed on opposing sides of a protruded portion of the substrate 302, with the nanostructures 304 disposed above the protruded portion. A gate structure 308 wraps around each of the nanostructures 304 (e.g., a full perimeter of each of the nanostructures 304). Source/drain structures 306 are disposed on opposing sides of the gate structure 308.

In some embodiments, the first transistor 102, second transistor 104, and third transistor 106 may have a first conductive type (e.g., PMOS). The first to third transistors can be operatively formed from a first active region (e.g., oxide diffusion (OD) active region) 150 extending along a first lateral direction (e.g., X-direction). Each of the first to third transistors may have a respective gate structure 122, 124, 126 extending along a second lateral direction (e.g., Y-direction). The gate structures of the first to third transistors each may have a first length/measurement/dimension/width (e.g., D1−a) extending in the first lateral direction.

In some embodiments, the fourth transistor 108, fifth transistor 110, sixth transistor 112, and seventh transistor 114 may have a second conductive type (e.g., NMOS). The fourth to seventh transistors can be operatively formed from a second active region (e.g., OD active region) 160 extending along the first lateral direction (e.g., X-direction). Each of the fourth to seventh transistors may have a respective gate structure 128, 130, 132, 134 extending along the second lateral direction (e.g., Y-direction). The gate structures of the fourth to seventh transistors each may have a second length/measurement/dimension/width (e.g., D1) extending in the first lateral direction. In some embodiments, the first length/measurement/dimension/width (e.g., D1−a) can be shorter than the second length/measurement/dimension/width (e.g., D1). In some embodiments, the first measurement and the second measurement can be different from each other with a difference (e.g., a). A ratio of the difference to the second measurement (e.g., a/D1) can be between about 0.05 and about 0.5 (e.g., 0.05<a/D1<0.5).

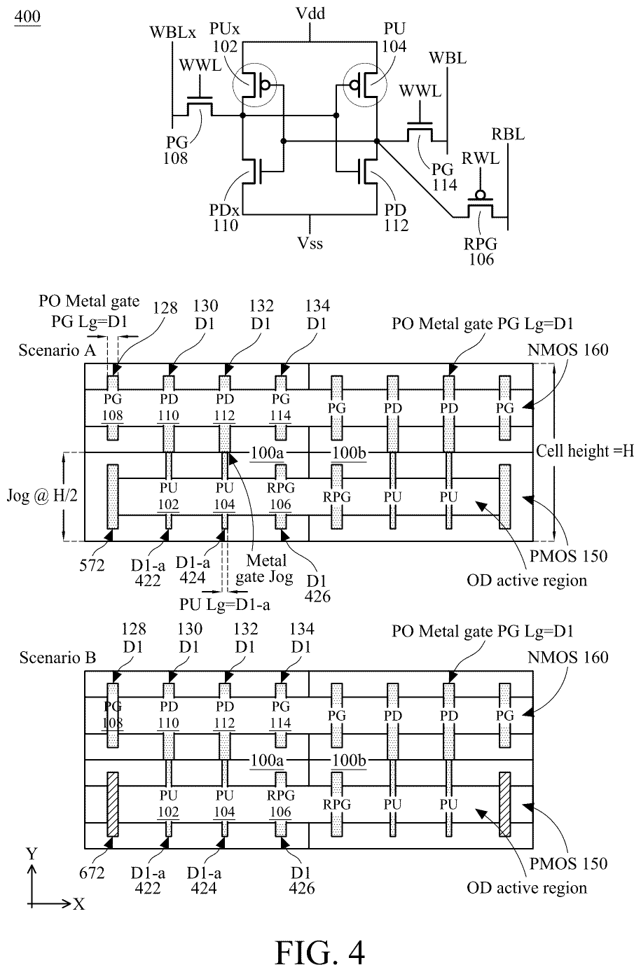

FIG. 4 illustrates an example layout design of an example memory device 400 with hybrid gate structures, in accordance with some embodiments. FIG. 4 illustrates an alternative example of FIG. 1 by reducing measurements/dimensions/widths of pull-up (PU) transistors 102, 104. FIG. 4 shows a memory device 400 with a plurality of memory cells 100a, 100b. One or more peripheral circuits (not shown) may be located at one or more regions peripheral to, or within, the memory cells 100a, 100b. In the illustrated embodiment of FIG. 4, the memory cell can be an example of a seven transistor (7T) SRAM cell 100a, 100b. The memory cell 100a, 100b may include first (e.g., pull-up (PU) transistor) transistor 102, second (e.g., PU transistor) transistor 104, third (e.g., read pass gate (RPG) transistor) transistor 106, fourth (e.g., pass gate (PG) transistor) transistor 108, fifth (e.g., pull-down (PD) transistor) transistor 110, sixth (e.g., PD transistor) transistor 112, and seventh (e.g., PG transistor) transistor 114. In some embodiments, the memory cell may include a Static Random Access Memory (SRAM) cell. The memory device 400 of FIG. 4 is substantially similar to the memory device 100 of FIG. 1, except for measurements/dimensions/widths of pull-up (PU) transistors 422, 424 and read pass gate (RPG) transistor 426. In some embodiments, scenario A pertains to gate structure 128 of the fourth transistor 108, while the other gate structure 572 may include one or more similar metal materials. Scenario B relates to gate structure 128 of the fourth transistor 108, and the other gate structure 672 can be formed from different materials.

In some embodiments, the first transistor 102, second transistor 104, and third transistor 106 may have a first conductive type (e.g., PMOS). The first to third transistors can be operatively formed from a first active region (e.g., oxide diffusion (OD) active region) 150 extending along a first lateral direction (e.g., X-direction). Each of the first to third transistors may have a respective gate structure 422, 424, 426 extending along a second lateral direction (e.g., Y-direction). The gate structures 422, 424 of the first transistor 102 and the second transistor 104 each may have a first length/measurement/dimension (e.g., D1−a) extending in the first lateral direction. The gate structure 426 of the third transistor 106 each may have a second length/measurement/dimension (e.g., D1) extending in the first lateral direction.

In some embodiments, the fourth transistor 108, fifth transistor 110, sixth transistor 112, and seventh transistor 114 may have a second conductive type (e.g., NMOS). The fourth to seventh transistors can be operatively formed from a second active region (e.g., OD active region) 160 extending along the first lateral direction (e.g., X-direction). Each of the fourth to seventh transistors may have a respective gate structure 128, 130, 132, 134 extending along the second lateral direction (e.g., Y-direction). The gate structures of the fourth to seventh transistors each may have the second length/measurement/dimension (e.g., D1) extending in the first lateral direction. In some embodiments, the first length/measurement/dimension (e.g., D1−a) can be shorter than the second length/measurement/dimension (e.g., D1). In some embodiments, the first measurement and the second measurement can be different from each other with a difference (e.g., a). A ratio of the difference to the second measurement (e.g., a/D1) can be between about 0.05 and about 0.5 (e.g., 0.05<a/D1<0.5).

The memory device 400 utilizes a hybrid metal gate configuration specifically designed to optimize VDDR levels. In this configuration, the gate measurements/dimensions/lengths are defined as follows: the pull-down gate measurements/dimensions/lengths (PG Lg) and the read pass gate measurements/dimensions/lengths (RPG Lg) are both set to D1, while the pull-up gate length (PU Lg) is determined by D1 minus a. For example, the variable a can be within a range of about 0.5 nm<a<about 5 nm. In some embodiments, a ratio of the variable a to D1 (e.g., a/D1) can be between about 0.05 and about 0.5 (e.g., 0.05<a/D1<0.5). In some embodiments, the metal gate features a jog positioned at half the cell height (e.g., H/2), with the hybrid gate measurements/dimensions/widths implemented in the pull-up gate (PU) and pull-down gate (PD). The pull-up gate measurements/dimensions/widths can be designed to be less than that of the read path gate (RPG). In certain embodiments, the read pass gate measurements/dimensions/widths may exceed that of the pull-down gate measurements/dimensions/widths. This design and configuration enhances the performance of the 7T SRAM cell, particularly in terms of reducing Vddr and improving overall efficiency. In some embodiments, a saturation current ratio, defined as Isat PU over Isat RPG (e.g., Isat PU/Isat RPG), can be set to be greater than 1. This indicates that the saturation current of the pull-up transistor may be higher than that of the read path gate, which enhances the write operation's efficiency and stability, thereby supporting the overall performance of the SRAM cell during write operations.

In some embodiments, the present application may provide a pull-up threshold voltage (PU Vt) of about −15 mV, resulting in a performance improvement of about 3 to 4%. This adjustment in threshold voltage significantly enhances the operational efficiency of the SRAM cell. In some embodiments, the saturation current ratio between the pull-up and read path gate transistors (PU/RPG) contributes to a saturation current increase of about 10 to 13%. This improvement optimizes the overall write and read performance of the cell. As a result of these enhancements, there is also a reduction in VDDR levels, achieving a decrease of about 60 to 70 mV.

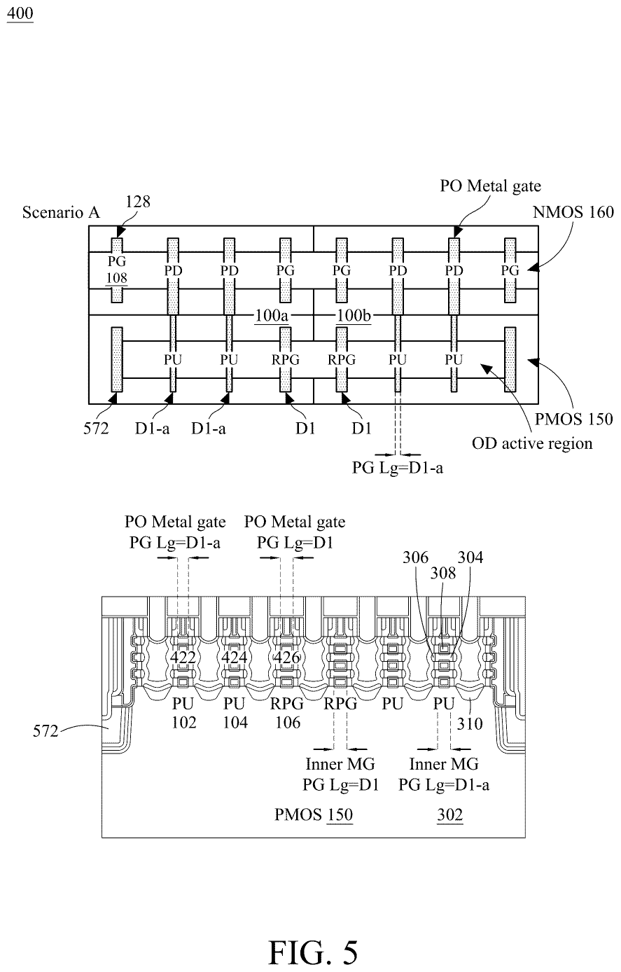

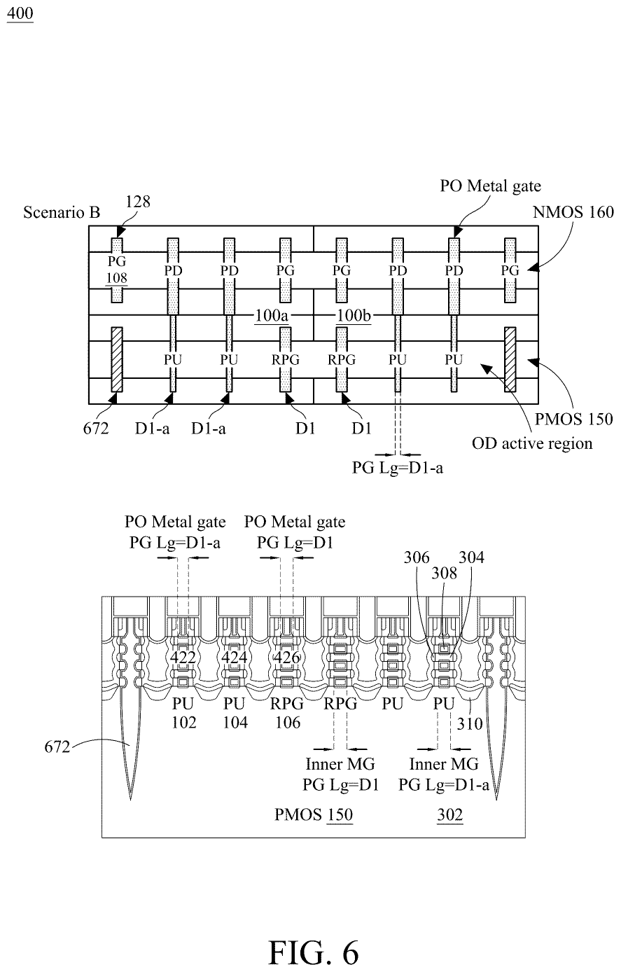

FIG. 5 illustrates an example layout design and a cross-sectional view of an example gate-all-around (GAA) field-effect-transistor (FET) device/memory device, in accordance with some embodiments. FIG. 6 illustrates an example layout design and a cross-sectional view of an example memory device, in accordance with some embodiments. The cross-sectional view of FIGS. 5 and 6 is cut along the lengthwise direction of the memory device 400 (e.g., X direction).

In FIG. 5, the gate structure 128 of the fourth transistor 108 can be disconnected from but aligned with another gate structure 572 traversing the first active region 150. In some embodiments, the gate structure 128 of the fourth transistor 108 and the another gate structure 572 may include one or more similar metal materials. In some embodiments, the first active region 150 may terminate at the another gate structure 572 along the first lateral direction (e.g., X-direction).

In FIG. 6, the gate structure 128 of the fourth transistor 108 can be disconnected from but aligned with another gate structure 672 traversing the first active region 150. In some embodiments, the gate structure 128 of the fourth transistor 108 and the another gate structure 672 can be formed of respective different materials. In some embodiments, the first active region 150 may extend beyond the another gate structure 672 along the first lateral direction (e.g., X-direction).

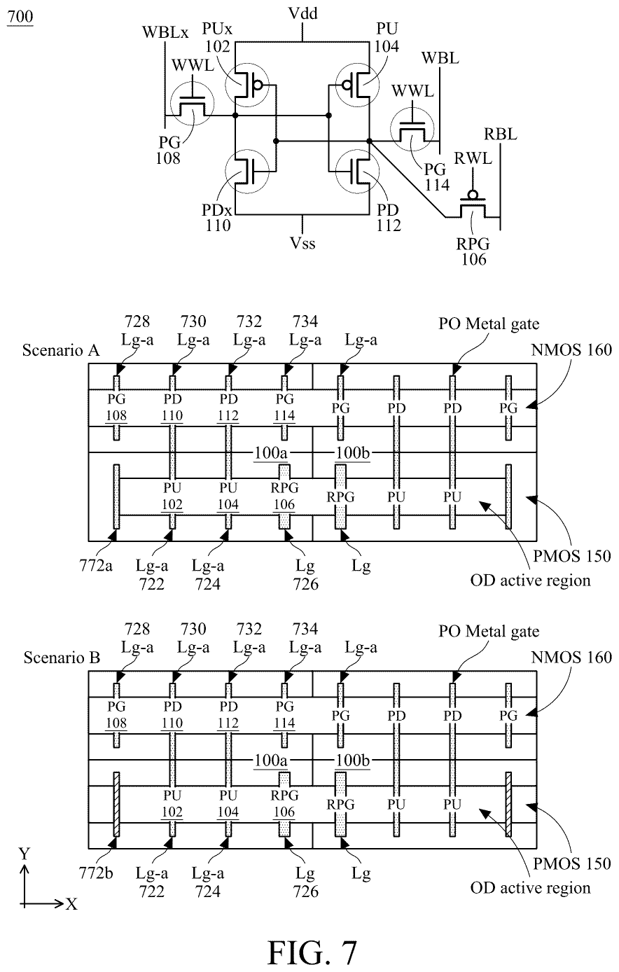

FIG. 7 illustrates an example layout design of an example gate-all-around (GAA) field-effect-transistor (FET) device/memory device with hybrid gate structures, in accordance with some embodiments. FIG. 7 illustrates an alternative example of FIG. 1 by reducing measurements/dimensions/widths of pass gate (PG) transistors 108, 114, pull-down (PD) transistors 110, 112, and pull-up (PU) transistors 102, 104. FIG. 7 shows a memory device 700 with a plurality of memory cells 100a, 100b. One or more peripheral circuits (not shown) may be located at one or more regions peripheral to, or within, the memory cells 100a, 100b. In the illustrated embodiment of FIG. 7, the memory cell can be an example of a seven transistor (7T) SRAM cell 100a, 100b. The memory cell 100a, 100b may include first (e.g., pull-up (PU) transistor) transistor 102, second (e.g., PU transistor) transistor 104, third (e.g., read pass gate (RPG) transistor) transistor 106, fourth (e.g., pass gate (PG) transistor) transistor 108, fifth (e.g., pull-down (PD) transistor) transistor 110, sixth (e.g., PD transistor) transistor 112, and seventh (e.g., PG transistor) transistor 114. In some embodiments, the memory cell may include a Static Random Access Memory (SRAM) cell. The memory device 400 of FIG. 4 is substantially similar to the memory device 100 of FIG. 1, except for measurements/dimensions/widths of pass gate (PG) transistors 108, 114, pull-down (PD) transistors 110, 112, and pull-up (PU) transistors 102, 104. In some embodiments, scenario A pertains to gate structure 728 of the fourth transistor 108, while the other gate structure 772a may include one or more similar metal materials. Scenario B relates to gate structure 728 of the fourth transistor 108, and the other gate structure 772b can be formed from different materials.

In some embodiments, the first transistor 102, second transistor 104, and third transistor 106 may have a first conductive type (e.g., PMOS). The first to third transistors can be operatively formed from a first active region (e.g., oxide diffusion (OD) active region) 150 extending along a first lateral direction (e.g., X-direction). Each of the first to third transistors may have a respective gate structure 722, 724, 726 extending along a second lateral direction (e.g., Y-direction). The gate structures 722, 724 of the first transistor 102 and the second transistor 104 each may have a first length/measurement/dimension (e.g., Lg−a) extending in the first lateral direction. The gate structure 726 of the third transistor 106 each may have a second length/measurement/dimension (e.g., Lg) extending in the first lateral direction. In some embodiments, the first length/measurement/dimension (e.g., Lg−a) can be shorter than the second length/measurement/dimension (e.g., Lg). In some embodiments, the first measurement and the second measurement can be different from each other with a difference (e.g., a). A ratio of the difference to the second measurement (e.g., a/Lg) can be between about 0.05 and about 0.5 (e.g., 0.05<a/Lg<0.5).

In some embodiments, the fourth transistor 108, fifth transistor 110, sixth transistor 112, and seventh transistor 114 may have a second conductive type (e.g., NMOS). The fourth to seventh transistors can be operatively formed from a second active region (e.g., OD active region) 160 extending along the first lateral direction (e.g., X-direction). Each of the fourth to seventh transistors may have a respective gate structure 728, 730, 732, 734 extending along the second lateral direction (e.g., Y-direction). The gate structures of the fourth to seventh transistors each may have the first length/measurement/dimension (e.g., Lg−a) extending in the first lateral direction.

The memory device 700 utilizes a hybrid metal gate configuration specifically designed to optimize Vddr levels. In this configuration, the pull-up gate measurements/dimensions/lengths (PU Lg) can be adjusted by a variable a, while the read pass/path gate length (RPG Lg) is maintained equal to Lg. The saturation current ratio, defined as Isat PU over Isat RPG, can be greater than 1, indicating that the pull-up transistor exhibits a higher saturation current than the read pass gate. In some embodiments, both the pull-up and pull-down gates incorporate Lg-a, can be within a range of about 0.5 nm<a<about 5 nm. This design choice results in the pull-up gate measurements/dimensions/lengths being less than that of the read path gate, while the read path gate length exceeds that of the pull-down gate. The ratio of the pull-up to read path gate saturation currents being greater than 1 facilitates improvements in both the pull-up transistor's performance and Vddr reduction. Furthermore, the NMOS transistors also benefit from about 4% enhancement in performance due to the implementation of reduced gate measurements/dimensions/lengths, contributing to the overall efficiency of the 7T SRAM architecture.

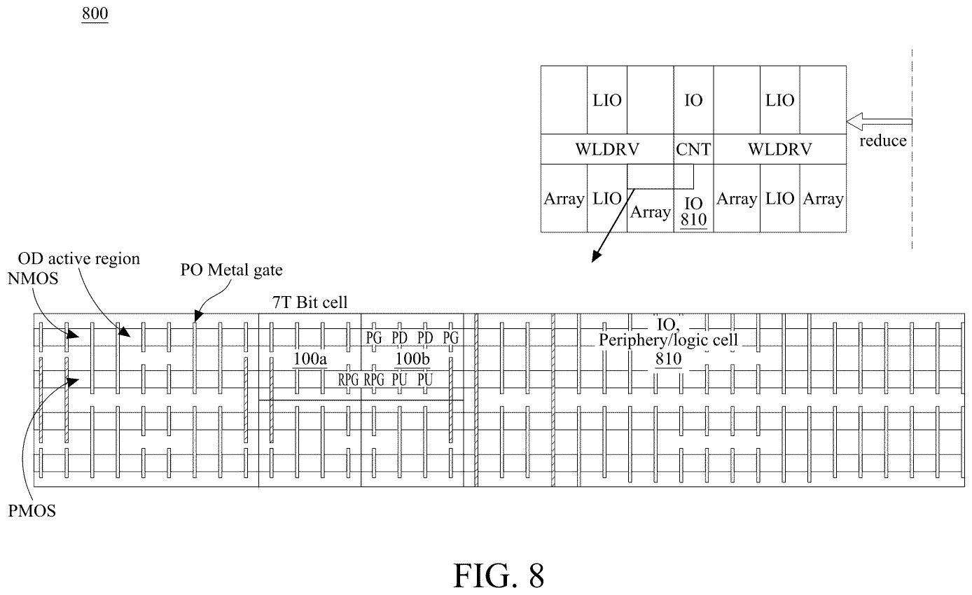

FIG. 8 illustrates an example layout design of an example gate-all-around (GAA) field-effect-transistor (FET) device/memory device with hybrid gate structures, in accordance with some embodiments. FIG. 8 presents an alternative example of FIG. 1 by introducing one or more peripheral circuits 810. FIG. 8 shows a memory device 100 with a plurality of memory cells 100a, 100b, as well as one or more peripheral circuits 810. In some embodiments, the one or more peripheral circuits 810 may be located at one or more regions peripheral to, or within, the memory cells 100a, 100b. In some embodiments, the memory cell may include a Static Random Access Memory (SRAM) cell. The memory device 800 of FIG. 8 is substantially similar to the memory device 100 of FIG. 1, except for the inclusion of one or more peripheral circuits 810.

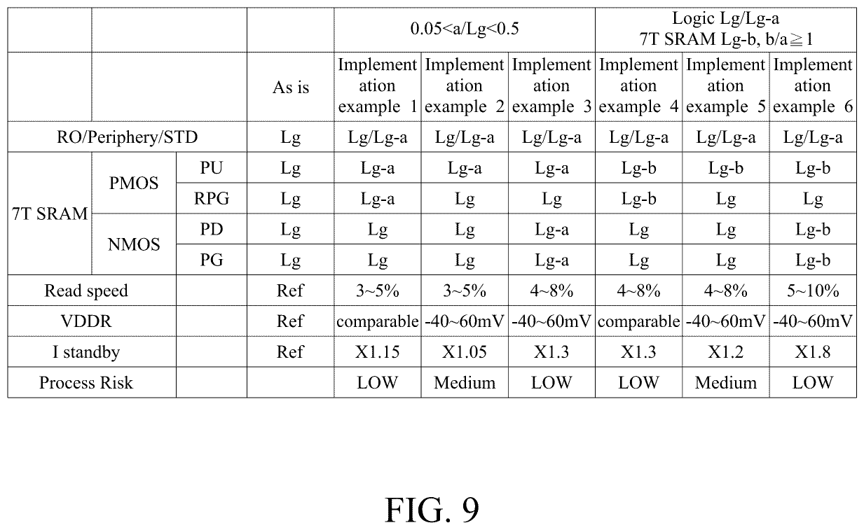

FIG. 9 illustrates an example table of different implementation examples of gate-all-around (GAA) field-effect-transistor (FET) device/memory devices with hybrid gate structures, in accordance with some embodiments. The table outlines various parameters and performance metrics associated with the implementation of 7T SRAM technology across different implementation examples. The table includes key factors such as read speed, VDDR, and standby current (I standby) for various configurations. The process risk is categorized, showing variations labeled as “As is,” with differing logic gate measurements/dimensions/lengths (Lg) and adjustments (Lg−a, Lg−b). Each example presents comparative metrics for logic length ratios and performance improvements, indicating enhancements in read speeds ranging from about 3% to 10%. Additionally, VDDR reductions are noted as being comparable across configurations, with shifts around about −40 to −60 mV. The table also provides a qualitative assessment of the implementation risks, labeling them as low or medium, thus offering insights into the trade-offs associated with different SRAM designs.

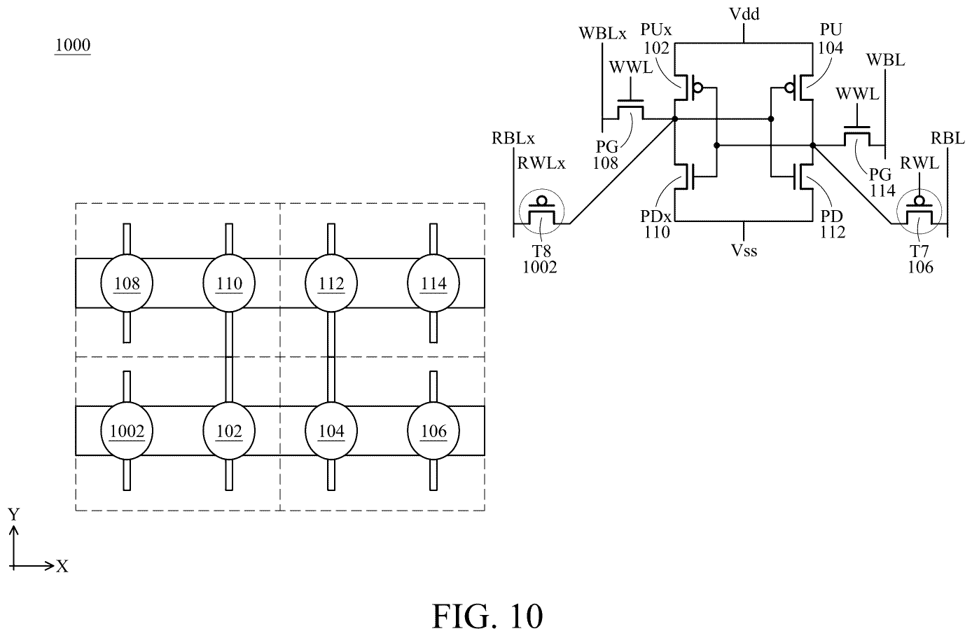

FIG. 10 illustrates an example layout design of an example gate-all-around (GAA) field-effect-transistor (FET) device/memory device with hybrid gate structures, in accordance with some embodiments. FIG. 10 illustrates an alternative example of FIG. 1 by introducing 8-transistor (8T) configuration. One or more peripheral circuits (not shown) may be located at one or more regions peripheral to, or within, the memory cells. In the illustrated embodiment of FIG. 10, the memory cell can be an example of an eight transistor (8T) SRAM cell. The memory cell 1000 may include first (e.g., pull-up (PU) transistor) transistor 102, second (e.g., PU transistor) transistor 104, third (e.g., read pass gate (RPG) transistor) transistor 106, fourth (e.g., pass gate (PG) transistor) transistor 108, fifth (e.g., pull-down (PD) transistor) transistor 110, sixth (e.g., PD transistor) transistor 112, seventh (e.g., PG transistor) transistor 114, and eighth transistor 1002. In some embodiments, the memory cell may include a Static Random Access Memory (SRAM) cell. The memory device 1000 of FIG. 10 is substantially similar to the memory device 100 of FIG. 1, except for eighth transistor 1002. The gate structure measurements/dimensions/lengths of the 8T SRAM can be adjusted based on varying requirements. Various parameters and performance metrics associated with the gate structures of 8T SRAM technology across different implementation examples can be optimized to enhance both speed and power efficiency in SRAM configurations. The new 8T and 7T transistors can be designed with a cell width of 4 OD isolation pitches, meaning the transistors are physically smaller. The transition from 5 oxide diffusion (OD) isolation pitches to 4 OD isolation pitches allows for a more compact design in transistor layouts. In some embodiments, 4 OD isolation pitches refer to the spacing used for isolation regions in semiconductor device design. “4 OD isolation pitches” means that the distance between adjacent isolation regions is equivalent to four times the typical oxide diffusion pitch. This reduction in isolation pitch allows for a more compact layout of devices, improving the overall density of the circuit.

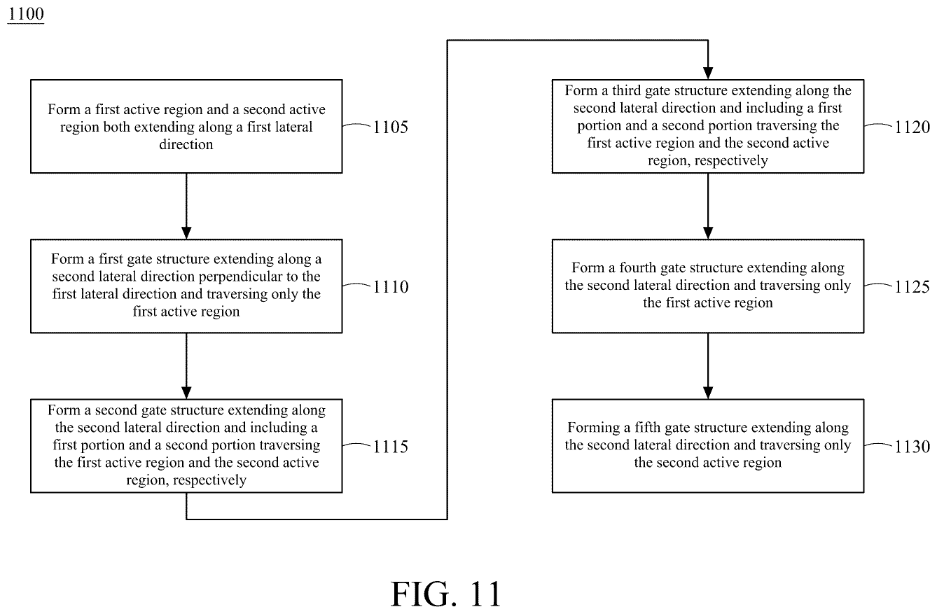

FIG. 11 illustrates an example flow chart for forming a gate-all-around (GAA) field-effect-transistor (FET) device/memory device 100 of FIG. 1, in accordance with some embodiments. It is understood that FIG. 11 and FIG. 1 have been simplified for a better understanding of the concepts of the present disclosure. Accordingly, it should be noted that additional processes may be provided before, during, and after the method of FIG. 11, and that some other processes may only be briefly described herein.

Referring to operation 1105, and in some embodiments, a first active region 160 and a second active region 150 both extending along a first lateral direction (e.g., X-direction) can be formed. The first active region 160 may have a first conductive type (e.g., N-type). The second active region 150 may have a second conductive type (e.g., P-type).

Next, the method 1100 proceeds to operation 1110 of forming a first gate structure 128 extending along a second lateral direction (e.g., Y-direction) perpendicular to the first lateral direction and traversing only the first active region 160. The first gate structure 128 may have a first length/measurement/dimension/width in the first lateral direction (e.g., X-direction) (e.g., Lg).

Next, the method 1100 proceeds to operation 1115 of forming a second gate structure 130, 122 extending along the second lateral direction (e.g., Y-direction). The second gate structure 130, 122 may include a first portion 130 and a second portion 122 traversing the first active region 160 and the second active region 150, respectively. The first portion 130 of the second gate structure may have a first length/measurement/dimension/width (e.g., Lg) in the first lateral direction (e.g., X-direction). The second portion of the second gate structure may have a second length/measurement/dimension/width (e.g., Lg−a) in the first lateral direction (e.g., X-direction).

Next, the method 1100 proceeds to operation 1120 of forming a third gate structure 132, 124 extending along the second lateral direction (e.g., Y-direction). The third gate structure 132, 124 may include a first portion 132 and a second portion 124 traversing the first active region 160 and the second active region 150, respectively. The first portion 132 of the third gate structure may have a first length/measurement/dimension/width (e.g., Lg) in the first lateral direction (e.g., X-direction). The second portion 124 of the third gate structure may have a second length/measurement/dimension/width (e.g., Lg−a) in the first lateral direction (e.g., X-direction).

Next, the method 1100 proceeds to operation 1125 of forming a fourth gate structure 134 extending along the second lateral direction (e.g., Y-direction) and traversing only the first active region 160. The fourth gate structure 134 may have a first length/measurement/dimension/width (e.g., Lg) in the first lateral direction (e.g., X-direction).

Next, the method 1100 proceeds to operation 1130 of forming a fifth gate structure 126 extending along the second lateral direction (e.g., Y-direction) and traversing only the second active region 150. The fifth gate structure 126 may have a second length/measurement/dimension/width (e.g., Lg−a) in the first lateral direction (e.g., X-direction).

In some embodiments, the first gate structure 128, the first portion 130 of the second gate structure, the first portion 132 of the third gate structure, and the fourth gate structure 134 each may have a first length/measurement/dimension/width (e.g., Lg) in the first lateral direction (e.g., X-direction). The second portion 122 of the second gate structure, the second portion 124 of the third gate structure, and the fifth gate structure 126 each may have a second length/measurement/dimension/width (e.g., Lg−a) in the first lateral direction (e.g., X-direction). In some embodiments, the first measurement can be longer than the second measurement. In some embodiments, the first measurement and the second measurement can be different from each other with a difference (e.g., a). A ratio of the difference to the first length/measurement/dimension (e.g., a/Lg) can be between about 0.05 and about 0.5 (e.g., 0.05<a/Lg<0.5).

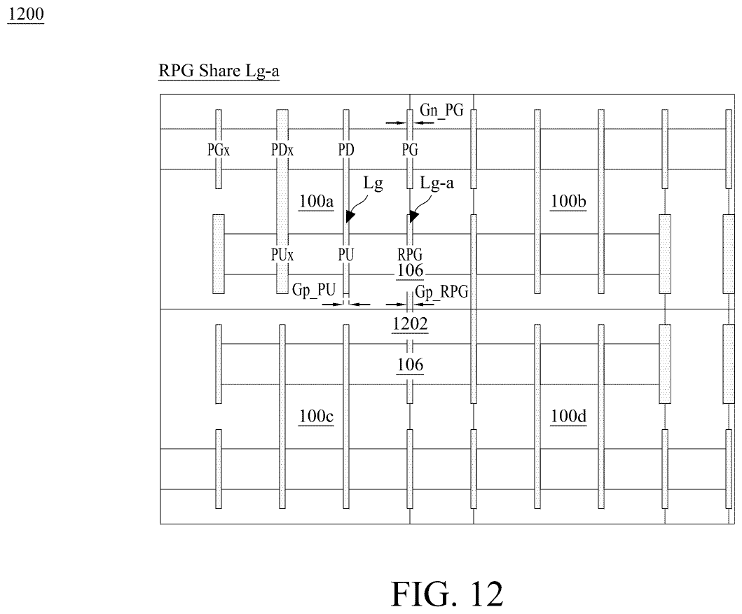

FIG. 12 illustrates an example layout design of an example gate-all-around (GAA) field-effect-transistor (FET) device/memory device with hybrid gate structures, in accordance with some embodiments. FIG. 8 presents an alternative example of FIG. 1 by introducing a plurality of memory cells 100a, 100b, 100c, 100d. In some embodiments, the plurality of memory cells 100a, 100b, 100c, and 100d may share the read pass gate (RPG) transistors 106. The RPG transistors utilize a reduced gate dimension 1202 (e.g., Lg−a), where Lg refers to a metal gate that serves both pull-up (PU) and pull-down (PD) functions. For example, the memory devices 100a and 100c may share the RPG 1202. Using the gate dimensions (e.g., Lg−a) in the read pass gate (RPG) transistors may result in a speed improvement of about 4%. In some embodiments, the memory cells may include Static Random Access Memory (SRAM) cells. The memory device 1200 in FIG. 12 is substantially similar to the memory device 100 in FIG. 1,

except for the shared RPG 1202.

In one aspect of the present disclosure, a memory device is disclosed. The memory device may comprise a memory cell including first, second, third, fourth, fifth, sixth, and seventh transistors. The first, second, and third transistors may have a first conductive type. The fourth, fifth, sixth, and seventh transistors may have a second conductive type. The first to third transistors can be operatively formed from a first active region extending along a first lateral direction and each may have a respective gate structure extending along a second lateral direction. The fourth to seventh transistors can be operatively formed from a second active region extending along the first lateral direction and each may have a respective gate structure extending along the second lateral direction. The gate structures of the first to third transistors each may have a first measurement extending in the first lateral direction. The gate structures of the fourth to seventh transistors each may have a second measurement extending in the first lateral direction. In some embodiments, the first measurement can be shorter than the second measurement.

In another aspect of the present disclosure, a semiconductor device is disclosed. The semiconductor device may comprise a first active region extending along a first lateral direction and having a first conductive type; a second active region extending along the first lateral direction and having a second conductive type; a first gate structure extending along a second lateral direction perpendicular to the first lateral direction and traversing only the first active region; a second gate structure extending along the second lateral direction and traversing both the first and second active regions; a third gate structure extending along the second lateral direction and traversing both the first and second active regions; a fourth gate structure extending along the second lateral direction and traversing only the first active region; and a fifth gate structure extending along the second lateral direction and traversing only the second active region. The first gate structure, a first portion of the second gate structure traversing the first active region, a first portion of the third gate structure traversing the first active region, and the fourth gate structure each may have a first measurement in the first lateral direction. A second portion of the second gate structure traversing the second active region, a second portion of the third gate structure traversing the second active region, and the fifth gate structure each may have a second measurement in the first lateral direction. In some embodiments, the first measurement can be longer than the second measurement.

In yet another aspect of the present disclosure, a method for forming a memory device. The method may comprise forming a first active region and a second active region both extending along a first lateral direction. The first active region may have a first conductive type and the second active region may have a second conductive type. The method may comprise forming a first gate structure extending along a second lateral direction perpendicular to the first lateral direction and traversing only the first active region. The method may comprise forming a second gate structure extending along the second lateral direction and including a first portion and a second portion traversing the first active region and the second active region, respectively. The method may comprise forming a third gate structure extending along the second lateral direction and including a first portion and a second portion traversing the first active region and the second active region, respectively. The method may comprise forming a fourth gate structure extending along the second lateral direction and traversing only the first active region. The method may comprise forming a fifth gate structure extending along the second lateral direction and traversing only the second active region. The first gate structure, the first portion of the second gate structure, the first portion of the third gate structure, and the fourth gate structure each may have a first measurement in the first lateral direction. The second portion of the second gate structure, the second portion of the third gate structure, and the fifth gate structure each may have a second measurement in the first lateral direction. In some embodiments, the first measurement can be longer than the second measurement.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory cell including first, second, third, fourth, fifth, sixth, and seventh transistors, in which the first, second, and third transistors have a first conductive type, and the fourth, fifth, sixth, and seventh transistors have a second conductive type;
wherein the first to third transistors are operatively formed from a first active region extending along a first lateral direction and each have a respective gate structure extending along a second lateral direction, and the fourth to seventh transistors are operatively formed from a second active region extending along the first lateral direction and each have a respective gate structure extending along the second lateral direction;
wherein the gate structures of the first to third transistors each have a first measurement extending in the first lateral direction, and the gate structures of the fourth to seventh transistors each have a second measurement extending in the first lateral direction; and
wherein the first measurement is shorter than the second measurement.

2. The memory device of claim 1, wherein the memory cell includes a Static Random Access Memory (SRAM) cell.

3. The memory device of claim 1, wherein the first measurement and the second measurement are different from each other with a difference, and a ratio of the difference to the second measurement is between about 0.05 and about 0.5.

4. The memory device of claim 1, wherein the gate structure of the first transistor and the gate structure of the fifth transistor are connected to each other along the second lateral direction, and the gate structure of the second transistor and the gate structure of the sixth transistor are connected to each other along the second lateral direction.

5. The memory device of claim 1, wherein the gate structure of the seventh transistor and the gate structure of the third transistor are disconnected from but aligned with each other along the second lateral direction.

6. The memory device of claim 1, wherein the gate structure of the fourth transistor is disconnected from but aligned with another gate structure traversing the first active region.

7. The memory device of claim 6, wherein the gate structure of the fourth transistor and the another gate structure include one or more similar metal materials.

8. The memory device of claim 7, wherein the first active region terminates at the another gate structure along the first lateral direction.

9. The memory device of claim 6, wherein the gate structure of the fourth transistor and the another gate structure are formed of respective different materials.

10. The memory device of claim 9, wherein the first active region extends beyond the another gate structure along the first lateral direction.

11. A semiconductor device, comprising:
a first active region extending along a first lateral direction and having a first conductive type;
a second active region extending along the first lateral direction and having a second conductive type;
a first gate structure extending along a second lateral direction perpendicular to the first lateral direction and traversing only the first active region;
a second gate structure extending along the second lateral direction and traversing both the first and second active regions;
a third gate structure extending along the second lateral direction and traversing both the first and second active regions;
a fourth gate structure extending along the second lateral direction and traversing only the first active region; and
a fifth gate structure extending along the second lateral direction and traversing only the second active region;
wherein the first gate structure, a first portion of the second gate structure traversing the first active region, a first portion of the third gate structure traversing the first active region, and the fourth gate structure each have a first measurement in the first lateral direction;
wherein a second portion of the second gate structure traversing the second active region, a second portion of the third gate structure traversing the second active region, and the fifth gate structure each have a second measurement in the first lateral direction; and
wherein the first measurement is longer than the second measurement.

12. The semiconductor device of claim 11, wherein the first gate structure and the first active region operatively form a fourth transistor of a memory cell, the first portion of the second gate structure and the first active region operatively form a fifth transistor of the memory cell, the second portion of the second gate structure and the second active region operatively form a first transistor of the memory cell, the first portion of the third gate structure and the first active region operatively form a sixth transistor of the memory cell, the second portion of the third gate structure and the second active region operatively form a second transistor of the memory cell, the fourth gate structure and the first active region operatively form a seventh transistor of the memory cell, and the fifth gate structure and the second active region operatively form a third transistor of the memory cell.

13. The semiconductor device of claim 12, wherein the memory cell includes a Static Random Access Memory (SRAM) cell.

14. The semiconductor device of claim 11, wherein the first measurement and the second measurement are different from each other with a difference, and a ratio of the difference to the first measurement is between about 0.05 and about 0.5.

15. The semiconductor device of claim 11, wherein the first conductive type is N type, and the second conductive type is P type.

16. The semiconductor device of claim 11, wherein the first gate structure of the fourth transistor is disconnected from but aligned with another gate structure traversing the second active region.

17. The semiconductor device of claim 16, wherein the first gate structure of the fourth transistor and the another gate structure include one or more similar metal materials.

18. The semiconductor device of claim 16, wherein the first gate structure of the fourth transistor and the another gate structure are formed of respective different materials.

19. A method for forming a memory device, comprising:
forming a first active region and a second active region both extending along a first lateral direction, wherein the first active region has a first conductive type and the second active region has a second conductive type;
forming a first gate structure extending along a second lateral direction perpendicular to the first lateral direction and traversing only the first active region;
forming a second gate structure extending along the second lateral direction and including a first portion and a second portion traversing the first active region and the second active region, respectively;
forming a third gate structure extending along the second lateral direction and including a first portion and a second portion traversing the first active region and the second active region, respectively;
forming a fourth gate structure extending along the second lateral direction and traversing only the first active region; and
forming a fifth gate structure extending along the second lateral direction and traversing only the second active region;
wherein the first gate structure, the first portion of the second gate structure, the first portion of the third gate structure, and the fourth gate structure each have a first measurement in the first lateral direction;
wherein the second portion of the second gate structure, the second portion of the third gate structure, and the fifth gate structure each have a second measurement in the first lateral direction; and
wherein the first measurement is longer than the second measurement.

20. The method of claim 19, wherein the first measurement and the second measurement are different from each other with a difference, and a ratio of the difference to the first measurement is between about 0.05 and about 0.5.
